(19) United States
(12) Patent Application Publication
(10) Pub. No.: US 2012/0139603 A1
(43) Pub. Date: Jun. 7, 2012

(54) TUNABLE DELAY CELL APPARATUS

(75) Inventors: Shih-Hao Chen, Hsinchu City (TW); Hsiung-Kai Chen, Hsinchu City (TW); Shen-Chih Huang, Hsinchu City (TW)

(73) Assignees: Taiwan Semiconductor Manufacturing Company Limited, Hsinchu City (TW); Global Unichip Corporation, Hsinchu City (TW)

(21) Appl. No.: 13/308,735

(22) Filed: Dec. 1, 2011

(30) Foreign Application Priority Data
Dec. 2, 2010 (TW) 099141862

(51) Int. Cl. H03K 17/28

(52) U.S. Cl. 327/277

(57) ABSTRACT

A tunable delay cell (TDC) is disclosed, the TDC is applied to power gating circuit design, and the TDC is connected with control unit. The TDC comprises multiplexer, delay unit, clock signal input line, control signal line, power source terminal and combinational circuit. The signal provided by the control signal line can control the clock signal provided by the clock signal input line whether to be delayed a predetermined time by the delay unit or not. The control unit controls the combinational circuit to be turned off to make the TDC stop working.

### BACKGROUND OF THE INVENTION

1. Field of the Invention

This invention relates to a design field of the integrated circuit, particularly to a tunable delay cell (TDC) applied to power gating of integrated circuit design.

2. Description of the Prior Art

Low power has become an important consideration for current and the future logic circuit design with green energy and power conservation. Especially the common portable devices (such as cell phone or PDA etc.) have a lot of circuit blocks for the operation of various functions. Normally, the portable devices do not need to carry out all circuit blocks upon operating. Thus, how to close the circuit block without operating with the passed electric current, and can open it in time without influencing the performance while needing, will become one of the difficult problems which needs to be solved for power consumption.

The portable devices often have the problem of the standby leakage current. The main reason is that the standby leakage current will generate very large power consumption. Thus, in order to reduce the power demand and reduce the power consumption, break or isolate a block or sub-module can be considered. However, it is very hard to implement in the actual logic circuit structure.

As the above-mentioned description, the power switch is a common technique used at present. It can be used in the electronic device at the standby mode, and also can be used to turn off the specific block of chip of power supply of functional unit, in order to prevent the energy loss and reach the green energy effect of energy conversion. In general, there are two kinds of design for the power switch: off-chip control switch and on-chip control switch. The on-chip control switch can also be divided into the PAD Switch and the Core Power Switch. The design of PAD Switch often needs the additional input/output (I/O) space. The Core Power Switch is also abbreviated the power switch, which is the main design stream at present. In addition, the off-chip control switch needs to consume too much time to awake the circuit under control.

In the implementation of circuit design, the power switch number should be allocated enough to keep performance. In addition, in order to prevent IP/memory blocks from dynamic IR failure, the power switch and de-cap cells are allocated around memory block as well.

However, when the power switch is turn-on, a big in-rush current will be generated. If the in-rush current is too big, it will produce the adverse influence to the power network. If the power gating technique is used, it not only can reduce the standby leakage current effectively, but also can reduce the power consumption. In order to produce more efficient power switch circuit, it is necessary to research and develop novel power gating circuit to reach power consumption effect and reduce research and development cost.

### SUMMARY OF THE INVENTION

The purpose of the invention is to provide a power switch circuit and its tunable delay cell (TDC), in order to solve the above-mentioned problem.

In order to reach the above-mentioned purpose, a TDC is disclosed in the present invention; the TDC is connected with a combinational circuit and is applied to power switch design. The TDC comprises a multiplexer, a delay unit, a clock signal input line, a control signal line, a power source terminal and a switch unit. The multiplexer has a control input terminal, a first signal input terminal and a second signal input terminal. The delay unit includes a plurality of buffer units. The delay unit is connected to the first signal input terminal of the multiplexer. The clock signal input line is respectively connected to the delay unit and the second signal input terminal of multiplexer, and provides a clock signal. The control signal line is respectively connected to the delay unit and the control terminal of multiplexer. The signal provided by the control signal can control the clock signal provided by the clock signal input line whether to be delayed a predetermined time by the delay unit. The switch unit is connected to the power source terminal, control unit, multiplexer and delay unit. The combinational circuit controls the switch unit to be turned off to make the TDC stop working.

In an embodiment of the invention, the delay unit also comprises a logic unit, which is respectively connected to one of the plurality of buffer units, the clock signal input line, the control signal line, a logic unit and a gate unit.

In an embodiment of the invention, the multiplexer can delay the second predetermined time.

In an embodiment of the invention, the tunable delay unit is integrated in the countable delay cell.

In an embodiment of the invention, the countable delay cell comprises at least a tunable delay unit and a plurality of programmable capacitor delay units.

In order to reach the above-mentioned purpose, according to another tunable delay unit of the invention, it is respectively connected to the control unit and clock tree. The TDC comprises multiplexer, delay unit, clock signal input line, control signal line, power source terminal and switch unit. The multiplexer has a control input terminal, a first signal input terminal and a second signal input terminal. The delay unit includes a plurality of buffer units. The delay unit is connected to the first signal input terminal of the multiplexer. The clock signal input line is respectively connected to the delay unit and the second signal input terminal of multiplexer, and provides a clock signal. The control signal line is respectively connected to the delay unit and the control terminal of multiplexer. The signal provided by the control signal can control the clock signal provided by the clock signal input line whether to be delayed a predetermined time by the delay unit. The switch unit is connected to the power source terminal, control unit, multiplexer and delay unit. The combinational circuit controls the switch unit to be turned off to make the TDC stop working.

In an embodiment of the invention, the multiplexer even comprises an output terminal, which is used to connect the clock tree.

As the above-mentioned description, the tunable delay cell provided by the invention can be applied to power gating of integrated circuit design. The power switch can be turn-on at different time point through setting at least a tunable delay cell, so that the value of in-rush current can be limited within a predetermined value.

In addition, the tunable delay cell of the invention can balance clock tree for different modes, in order to minimize the power consumption.

Therefore, the advantage and spirit of the invention can be understood further by the following detail description of invention and attached Figures.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 is a graph illustrating the block diagram for the application of the invention in the clock tree.

FIG. 2A shows the block diagram for the application of the tunable delay cell disclosed in FIG. 1 to the delay circuit of power switch.

FIG. 2B is a graph illustrating the inside diagram of the median level delay unit disclosed in FIG. 2A.

FIG. 2C is a graph illustrating the inside diagram of the median level delay unit disclosed in FIG. 2A.

FIG. 3 shows the block diagram for the application of the countable delay cell disclosed in FIG. 2A to the actual circuit.

FIG. 4 shows the power switch circuit for the application of the tunable delay cell provided by a preferred embodiment of the invention.

### DESCRIPTION OF THE PREFERRED EMBODIMENT

As for the preferred embodiments of the invention, please refer to the following Figures and description.

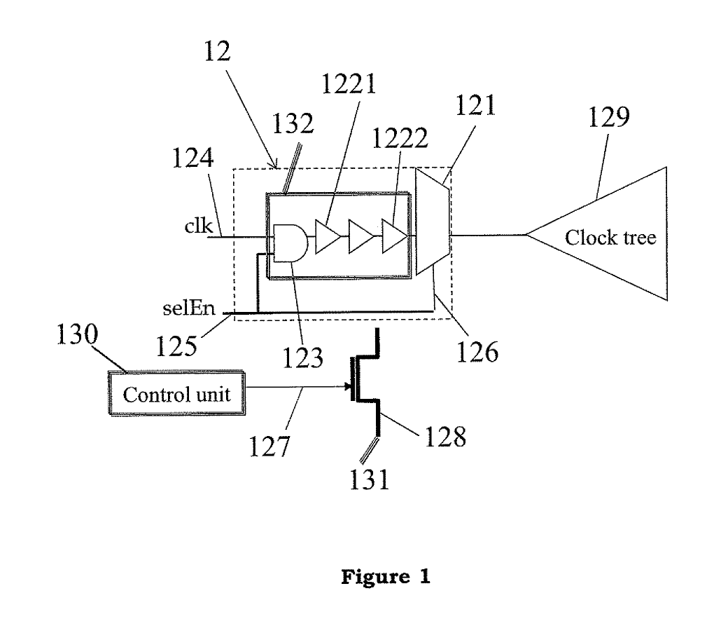

FIG. 1 is a graph illustrating the block diagram for the application of the invention in the clock tree. As shown in FIG. 1, a tunable delay cell 12 is connected with a control unit 130. A tunable delay cell (TDC) comprises a multiplexer 121, a delay unit 132, a clock signal input line 124, a control signal line 125, combinational a circuit 128 and a power source terminal 131. A delay unit 132 comprises a plurality of buffer unit 1221, a buffer unit 1222 and a logic unit 123. An output terminal of the tunable delay cell 12 provided by the invention can be connected to a clock tree 129.

The multiplexer 121 has a control terminal, a first signal input terminal, a second signal input terminal and an output terminal (not shown in the FIG. 1). The logic unit 123 has a first input terminal, a second input terminal and an output terminal (not shown in the FIG. 1).

The above-mentioned the buffer unit 1221, the buffer unit 1222 are connected to the logic unit 123 and the first signal input terminal of the multiplexer 121. In addition, in other embodiment, the logic unit 123 can be designed as different single logic unit or combination of a plurality of logic units in accordance with the input signal and requirement of circuit design, which is not limited in the invention. In the embodiment, the amount of the above-mentioned buffer unit 1221, the buffer unit 1222 can be increased or decreased in accordance with the required delay time. The invention does not limit the amount of the buffer unit 1221, the buffer unit 1222. In addition, the control signal line 125 is connected to the logic unit 123 and the multiplexer 121 electrically. The control signal line 125 is used to determine whether the signal inputted by the clock signal input line 124 has to pass through the buffer unit 1221, and the buffer unit 1222. For example, when the output signal of the control signal line 125 is “0”, the signal inputted by the clock signal input line 124 will enter into the multiplexer 121 directly. When the output signal of the control signal line 125 is “1”, the signal inputted by the clock signal input line 124 will pass through the buffer unit 1221, and the buffer unit 1222, and then enter into the multiplexer 121.

In the embodiment, every buffer unit 1221, the buffer unit 1222 respectively has a delay time. Because the embodiment is applied in clock tree, so the buffer unit 1221, and the buffer unit 1222 can balance the data transmission sequence of clock tree.

Clock signal input line 124 is respectively connected to the logic unit 123 and second signal input terminal of multiplexer 121. The control signal line 125 is respectively connected to logic unit 123 and control input terminal of multiplexer 121.

In the embodiment, the output of the multiplexer 121 can be controlled by the signal provided by the control signal line 125. It means the signal provided by the control signal line 125 can control the clock signal provided by the clock signal input line 124 whether to be delayed a first predetermined time by the delay unit 132 or not. For example, when the signal provided by the control signal line 125 is the high level signal, the output of the multiplexer 121 is the signal delayed by the buffer unit 1221, the buffer unit 1222. When the signal provided by the control signal line 125 is the low level signal, the output of the multiplexer 121 is the clock signal provided by the clock signal input line 124, which is the input signal without the delay treatment.

The above combinational circuit 128 is connected to the power source terminal 131, the control unit 130, and the delay unit 132, which controls whether the power provided by power source terminal 131 can be sent to the tunable delay cell 12, in order to control the operation of the tunable delay cell 12. At some time, for example, after the delayed clock signal is outputted by the multiplexer 121, the control unit 130 can control the operation of the combinational circuit 128, so that the combinational circuit 128 is turn-off, and the power source terminal 131 stops to provide the power to the tunable delay cell 12 to make tunable delay cell stops operating.

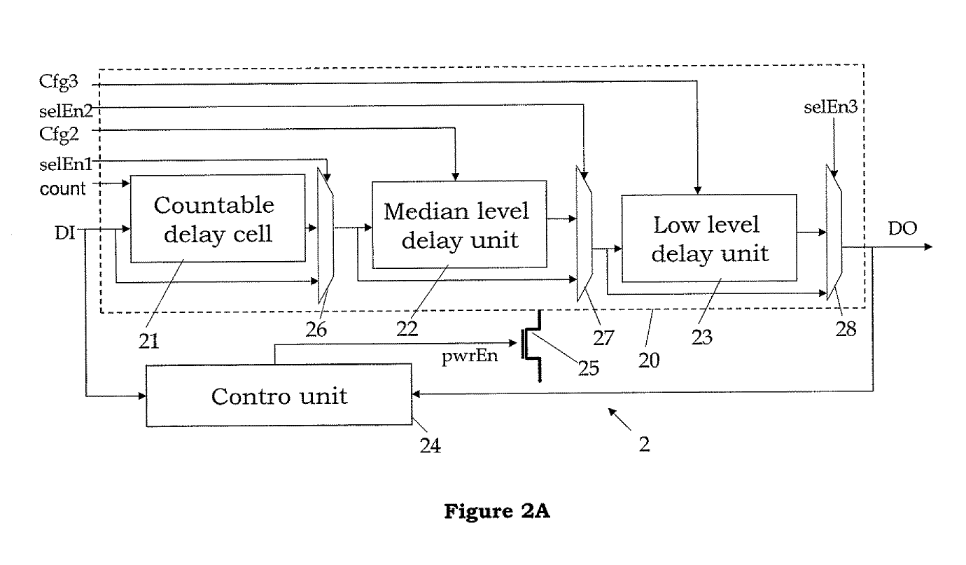

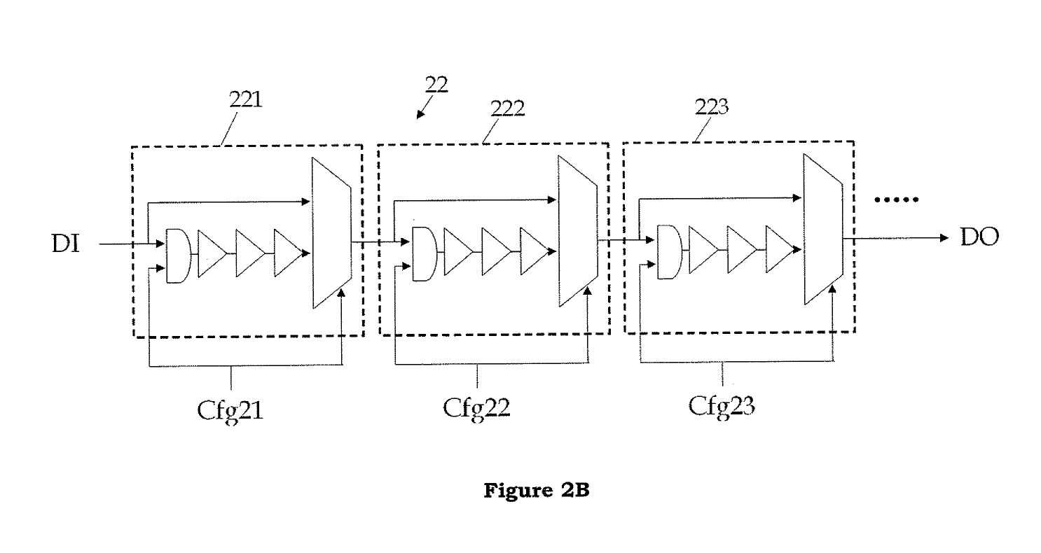

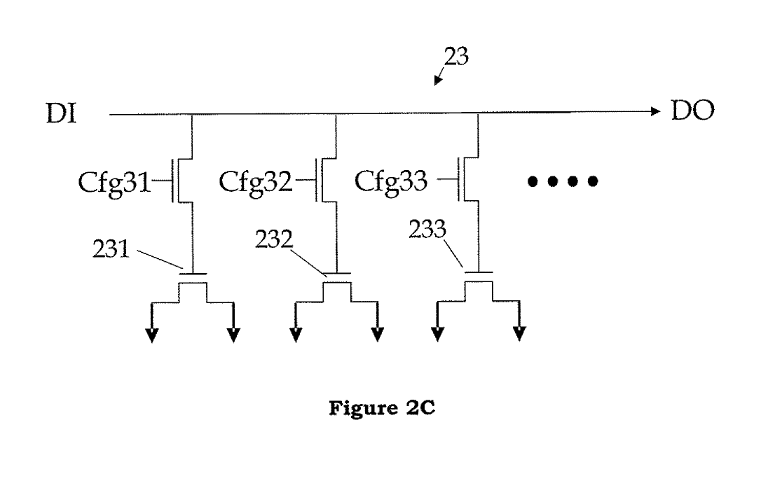

FIG. 2A shows the block diagram for the application of the tunable delay cell disclosed in FIG. 1 to the delay circuit of power switch. As shown in FIG. 2A, a delay circuit 2 comprises a delay block 20, a combinational circuit 25, and a control unit 24, wherein the delay block 20 comprises a countable delay cell 21, a median level delay unit 22, a low level delay unit 23, a multiplexer 26, a multiplexer 27, and a multiplexer 28. In the embodiment, the countable delay cell 21 is a high level delay unit.

In the embodiment, the range for the delay time of high level delay unit can be several nS to several mS. The range for the delay time of the median level delay unit 22 can be several pS to several nS. The delay time of the low level delay unit 23 can be several pS. However, these are not the limitation of the invention. For example, if this delay circuit is attempted to be used to reach 175 nS of total delay time, 170 nS of delay time can be provided by the delay cell 21, 4.5 nS of delay time can be provided by the delay cell 22, and 500 pS of delay time can be provided by the delay cell 23. Thus, the delay circuit of the invention can provide coarse, median, and fine control of delay time, in order to achieve precise delay control.

The above-mentioned delay block 20 can receive an input signal DI and many kinds of control signal, such as count, se1EN1, se1EN2, se1EN3, Cfg2, and Cfg3. These signals can be used with the delay block 20 to provide a delayed output signal DO.

The above-mentioned combinational circuit 25 can connect the delay block 20 to control the working power source of the delay block 20, and also control whether the delay block 20 or not is working. The control unit 24 can display the input signal DI and the output signal DO, which mainly control the operation of the combinational circuit 25, and further control whether the delay block 20 is working or not.

In the delay block 20 of the embodiment, the output of the countable delay cell 21 connects the multiplexer 26, the input of the median level delay unit 22 connects the multiplexer 26, the output of the median level delay unit 22 connects the multiplexer 27, the input of the low level delay unit 23 connects the multiplexer 27, the output of the low level delay unit 23 connects the multiplexer 28. Therefore, se1EN1, se1EN2, and se1EN3 signals of the multiplexer can be used to adjust the precision of delay time. It means se1EN1, se1EN2, and se1EN3 signals of the multiplexer can be used to determine whether the input signal DI has to enter into the countable delay cell 21, the median level delay unit 22, and the low level delay unit 23 to adjust time sequence. In other words, in the embodiment, the delay circuit applied in power switch can adjust the precision of delay time flexibly in accordance with different requirements. In other embodiment, the connection sequence of the countable delay cell 21, the median level delay unit 22, and the low level delay unit 23 can reversed randomly. The invention is not limited.

FIG. 2B is a graph illustrating the inside diagram of the median level delay unit disclosed in FIG. 2A. As shown in FIG. 2B, the median level delay unit 22 comprises a countable delay unit 221, a countable delay unit 222, and a countable delay unit 223 shown in FIG. 1. The description of the countable delay unit 221, the countable delay unit 222, and the countable delay unit 223 is similar to the embodiment of FIG. 1, which will not be explained again.

FIG. 2C is a graph illustrating the inside diagram of the median level delay unit disclosed in FIG. 2A. As shown in FIG. 2C, the low level delay unit 23 comprises a programmable capacitor delay unit 231, a programmable capacitor delay unit 232, and a programmable capacitor delay unit 233, and its range of delay time can be 10 pS˜1 nS.

As shown in FIG. 2A, according to the above-mentioned feature, the intensity of countable control signal, amount of tunable delay cell and/or programmable capacitor delay unit can be determined in accordance with the requirement, in order to reach more precise tunable delay time.

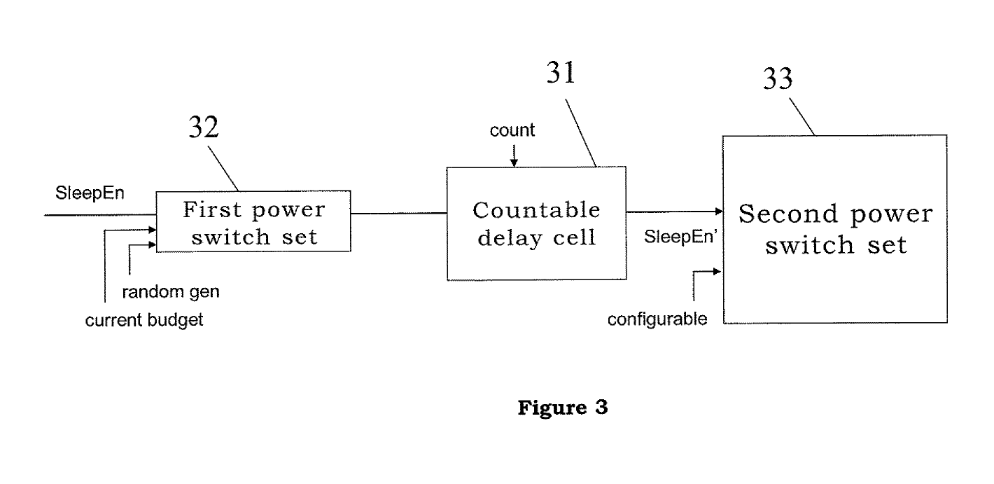

FIG. 3 shows the block diagram for the application of the countable delay cell disclosed in FIG. 2 to the actual circuit. A countable delay cell 31 is connected to a first power switch set 32 and a second power switch set 33. The countable delay cell 31 can receive a count signal to set its delay time.

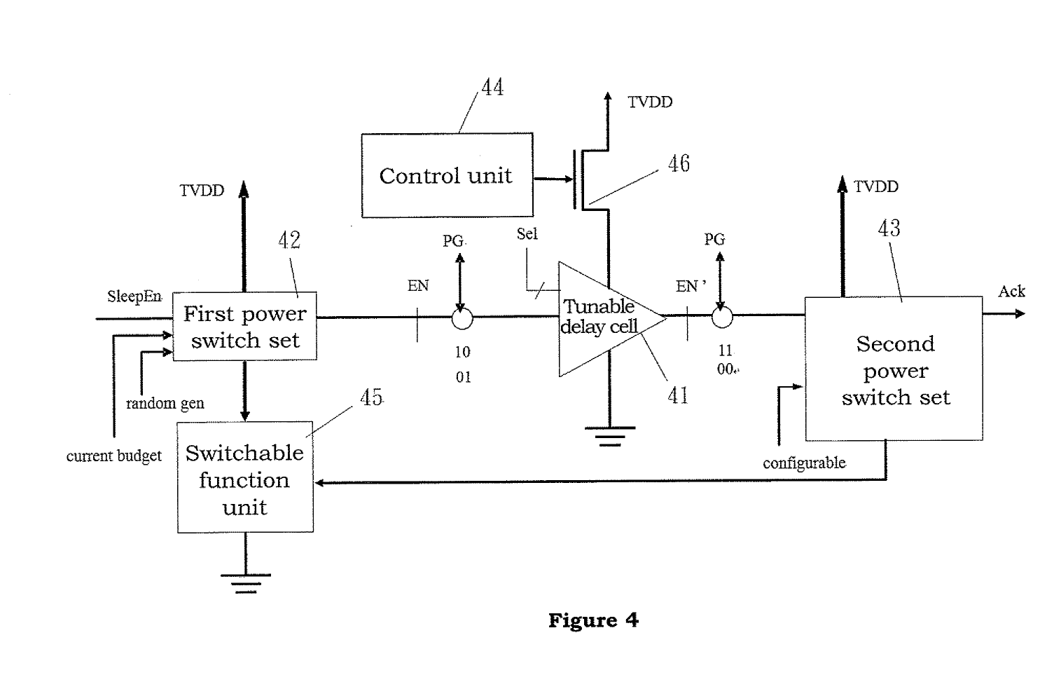

FIG. 4 shows the power switch circuit for the application of the tunable delay cell provided by a preferred embodiment of the invention. As shown in FIG. 4, the power switch circuit comprises a tunable delay cell 41, a first power switch set 42, a second power switch set 43, a control unit 44, a switchable function unit 45 and a combinational circuit 46, wherein the second power switch set 43 comprises a power switch chain.

The first power switch set 42 connects with the switchable function unit 45. The input terminal of the tunable delay cell 41 connects with the output terminal of the first power switch set 45. The combinational circuit 46 connects with the tunable delay cell 41 in order to control the power supply of the tunable delay cell 41. The control unit 44 connects with the combinational circuit 46 in order to control the operation of the combinational circuit 46, and further control the operation of the tunable delay cell 41. The input terminal of the second power switch set 43 connects with the output terminal of the tunable delay cell 41.

According to the tunable delay cell 41 provided by the above-mentioned embodiment, it is able to design required amount of buffer unit, and turn on or turn off the operation of the tunable delay cell 41 through the operation of the control unit 44 and the combinational circuit 46 at specific time. Therefore, when the power switch is turn-on, the generated in-rush current can be limited within a predetermined value, such as 150 mA.

Summarized from the above-mentioned description, the preferred embodiment of the invention provides a tunable delay cell. The tunable delay cell is used to provide a convenient design, so that the in-rush current generated at turn-on of power switch can be limited within a predetermined value.

It is understood that various other modifications will be apparent to and can be readily made by those skilled in the art without departing from the scope and spirit of this invention. Accordingly, it is not intended that the scope of the claims appended hereto be limited to the description as set forth herein, but rather that the claims be construed as encompassing all the features of patentable novelty that reside in the present invention, including all features that would be treated as equivalents thereof by those skilled in the art to which this invention pertains.

What is claimed is:

1. A tunable delay cell apparatus, connecting with a control unit and applied to a power switch, comprising:
a multiplexer having a control terminal, a first signal input terminal and a second signal input terminal;
a delay unit having a plurality of buffer units, the delay unit connecting with the first signal input terminal of the multiplexer;
a clock signal input line, respectively connecting to the delay unit and the second signal input terminal of the multiplexer and providing a clock signal;
a control signal line respectively connecting to the delay unit and the control terminal of the multiplexer in order to control the clock signal provided by the clock signal input line whether to be delayed a predetermined time by the delay unit or not;
a power source terminal; and
a combinational circuit connecting to the power source terminal, the control unit, the multiplexer and the delay unit; wherein the control unit controlling the combinational circuit to be turned off to make the tunable delay cell apparatus stop working.

2. The tunable delay cell apparatus according to claim 1, wherein the delay unit apparatus further comprises a logic unit, for connecting to one of the plurality of buffer units, the clock signal input line and the control signal line.

3. The tunable delay cell apparatus according to claim 2, wherein the logic unit comprises a logic and a gate unit.

4. The tunable delay cell apparatus according to claim 1, wherein the multiplexer can delay a second predetermined time.

5. The tunable delay cell apparatus according to claim 1, wherein the tunable delay cell apparatus being integrated in a countable delay cell.

6. The tunable delay cell apparatus according to claim 5, wherein the countable delay cell apparatus comprises at least a tunable delay cell and a plurality of programmable capacitor delay unit.

7. A tunable delay cell apparatus, respective connecting with a control unit and a clock tree, comprising:
a multiplexer, having a control terminal, a first signal input terminal and a second signal input terminal;
a delay unit, having a plurality of buffer units, wherein the delay unit connecting with the first signal input terminal of the multiplexer;
a clock signal input line, wherein the clock signal input line respectively connecting to the delay unit and the second signal input terminal of the multiplexer and providing a clock signal;
a control signal line, respectively connecting to the delay unit and the control terminal of the multiplexer in order to control the clock signal provided by the clock signal input line whether to be delayed a predetermined time by the delay unit or not;
a power source terminal; and
a combinational circuit connecting to the power source terminal, the control unit, the multiplexer and the delay unit; wherein the control unit controlling the combinational circuit to be turned off to make the tunable delay cell apparatus stop working.

8. The tunable delay cell apparatus according to claim 7, wherein the delay unit apparatus further comprises a logic unit for connecting to one of the plurality of buffer units, a clock signal input line and a control signal line.

9. The tunable delay cell apparatus according to claim 8, wherein the logic unit comprises a logic and a gate unit.

10. The tunable delay cell apparatus according to claim 7, wherein the multiplexer further comprises an output terminal to connect a clock tree.
